(19) United States
(12) Patent Application Publication
(10) Pub. No.: US 2018/0358801 A1
(43) Pub. Date: Dec. 13, 2018

(54) ELECTRICAL LINK COMPRISING AN ELECTRICAL PROTECTION DEVICE WITH INTEGRITY TEST

(71) Applicant: AIRBUS OPERATIONS (S.A.S.), Toulouse (FR)

(72) Inventor: Patrick OMS, Colomiers (FR)

(21) Appl. No.: 16/002,601

(22) Filed: Jun. 7, 2018

(30) Foreign Application Priority Data
Jun. 8, 2017 (FR) 1755085

(51) Int. Cl. H02H 5/10; H02H 1/00; B64D 45/00; G01R 19/00

(52) U.S. Cl. CPC H02H 5/10; H02H 1/0007; B64D 2221/00; G01R 19/0038; B64D 45/00

(57) ABSTRACT

An electrical link between a DC source and a user apparatus (250) including an electrical conductor (240) having an insulating cover and an electrical protection device (200) which includes: a conductive sleeve (280) around the insulating cover, a circuit breaker (210) on the electrical conductor (240), a biasing module (245) configured to voltage-bias the conductive sleeve (280) with a DC voltage; a device (250a) for limiting the bias voltage of the conductive sleeve having a limit voltage lower than the test voltage; and a detection module (220) connected to the conductive sleeve (280) and configured to detect a limiting of the bias voltage of the conductive sleeve by the limiting device (250a), and to command the circuit breaker (210) on the basis of the detection.

### RELATED APPLICATION

This application claims priority to French patent application 1755085 filed Jun. 8, 2017, the entirety of which is incorporated by reference.

### TECHNICAL FIELD

The present invention relates to an electrical link for transmission of a DC high voltage to a user apparatus. The electrical link comprises an electrical protection device for supplying electric power in a secure manner.

### BACKGROUND

An electrical power supply installation on an aircraft conventionally comprises an electric power source connected to an electrically powered user apparatus via an electrical link formed of an electrical conductor covered with an insulating cover. The conventional electrical link includes a circuit breaker that interrupts current in the conductor in response to an overload current or a short-circuit current in the conductor.

The demand for electric power on commercial aircraft has in recent years increased due to increasing demands of user devices in an aircraft. This increasing demand leads to a need power for increases in voltage levels of electric power supply systems on aircraft. For example, electrical power supply systems have in the past provided 115 volts AC (alternating current) and 28 volts DC (direct current). Current electrical power systems provide +/−270 volts DC or higher, such as 540 volts DC. The higher voltage levels in current aircraft electrical power supplies requires safety devices to, for example, ensure that aircraft maintenance staff may safely work on electrical systems in the event of disconnection or of breakage of an electrical link in the electrical supply installation. Conventional circuit breakers are not optimal, such as due to slow response times, for detecting a breakage of the electrical continuity of an electrical link.

### SUMMARY

There is a need to find a device that provides electrical protection of an electrical link so that high-voltage electric power may be supplied user apparatus(es) in a vehicle.

The invention relates to an electrical link designed to link a DC high-voltage power source to a user apparatus. The electrical link comprises an electrical conductor surrounded by an insulating cover and an electrical protection device including: a conductive sleeve arranged around the insulating cover, and a circuit breaker arranged on the electrical conductor and configured to cut off a current transiting through the conductor. The electrical protection device may further comprise: (i) a biasing module configured to voltage-bias the conductive sleeve with a DC test voltage; (ii) a device for limiting the bias voltage of the conductive sleeve having a limit voltage lower than the test voltage; and (iii) a detection module connected to the conductive sleeve and configured to detect a limiting, or lack thereof, of the bias voltage of the conductive sleeve by the limiting device, and to command the circuit breaker to interrupt current in the conductor if there is no limits of the biases voltage on the conductive sleeve.

The biasing module may comprise a DC voltage source supplying the test voltage, connected to the conductive sleeve.

The detection module may comprise: (i) a comparator with a first input connected to the conductive sleeve and whose second input is connected to a DC voltage generator supplying a reference voltage; and (ii) a microcontroller connected between an output of the comparator and the circuit breaker, the microcontroller being configured to send a command signal to the circuit breaker on the basis of an output signal received from the comparator. An insulating cover may surround the conductive sleeve.

The invention may be embodied to ensure that a high-voltage electric power supply is safely connected to a user apparatus in a vehicle, such as an aircraft. The invention may interrupt current in response to certain unsafe electrical conditions and thereby provide safety to maintenance staff working on the electrical link and user apparatus.

### BRIEF DESCRIPTION OF THE DRAWINGS

The features of the invention mentioned above, along with others, will become more clearly apparent on reading the following description of one exemplary embodiment, said description being given with reference to the appended drawings, in which:

FIG. 1 shows an aircraft including an electrical installation having a power source connected to a user apparatus via an electrical link and a current return line and a device for the electrical protection of the electrical link according to one embodiment of the invention;

FIG. 2 shows a block diagram of the electrical installation shown in FIG. 1, and a depiction of the device for the electrical protection of the electrical link according to one embodiment of the invention;

FIG. 3 shows a schematic view of a conductive sleeve arranged on an electrical link and forming part of the electrical protection device according to the invention;

FIG. 4 shows a circuit diagram of the electrical installation shown in FIG. 2; and

FIG. 5 is a diagram illustrating the evolution of voltages on the conductive sleeve according to FIG. 3.

### DETAILED DISCLOSURE OF EMBODIMENTS

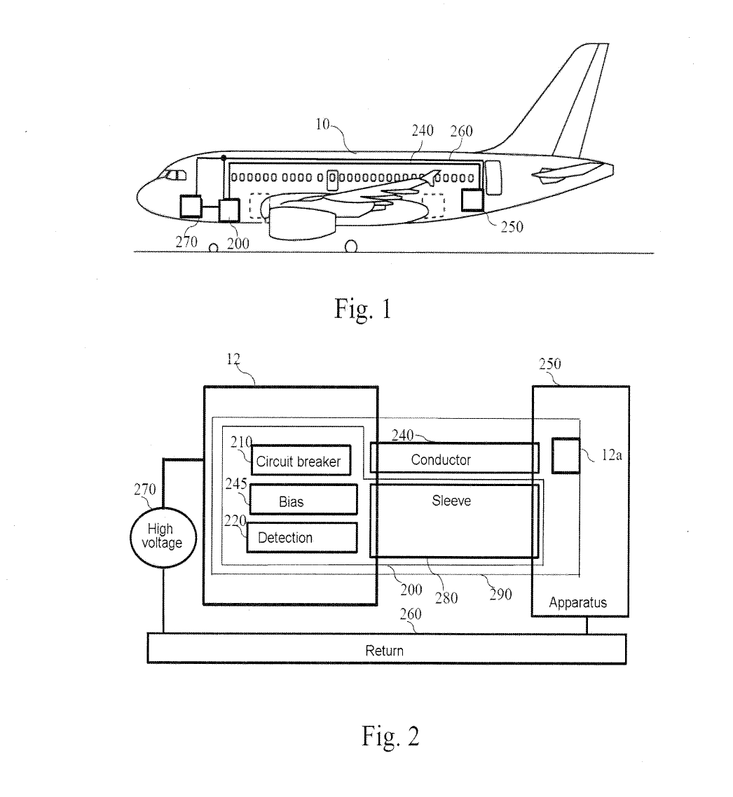

With reference to FIG. 1, an aircraft 10 includes an electrical installation having a high-voltage electric power source 270 connected to a user apparatus 250 via an electrical link 290 (FIG. 2) including a conductor 240, a current return line 260 and an electrical protection device 200.

The high-voltage electric power source 270 supplies a DC high voltage (HV) such as on the order of +/−270 volts DC, +/−540 volts DC or some other DC high voltage.

The aircraft 10 furthermore comprises a conductive structure (not shown) that is formed by any metal/conductive element of the aircraft that is at the reference potential and forms a ground for purposes of electricity in the aircraft.

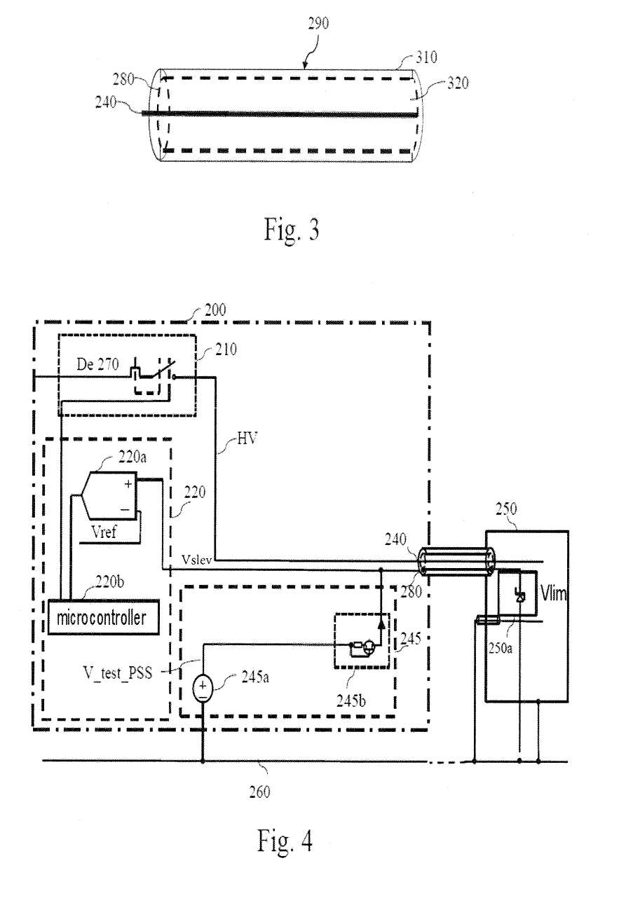

With reference to FIGS. 2 to 4, the electrical link 290 comprises an electrical conductor 240 surrounded by an insulating cover 320 (for example a plastic sleeve). A conductive sleeve 280 is a sleeve on the insulating cover 320. An insulating cover 310 is a sleeve on the conductive sleeve 280.

The electrical link 290 also includes the electrical protection device 200, configured to test electrical continuity of the conductive sleeve 280. The electrical protection device includes a conductive sleeve 280 on the insulating cover 320 of the conductor 240, and electrical devices including a circuit breaker 210, a biasing module 245 and a detection module 220.

The electronic devices, including the circuit breaker 210, biasing module 245, and detection module 220, are arranged in a secure housing 12 that may be situated upstream (that is to say on the side of the electric power source 270) of the electrical link 290. Voltage or signal limiting electronic devices 250a are arranged in a secure housing 12a situated downstream (that is to say on the side of the user apparatus 250) of the electrical link 290.

The voltage or signal limiting electronic device 250a limits (lowers) the voltage in the conductive sleeve 280. A break, crack or other physical interruption in the conductive sleeve prevents the limiting electronic device 250a from lowing the voltage Vslev on the conductive sleeve at the opposite end of the sleeve 280 near the electrical protective device 200. Thus, an increase in the voltage Vslev at the opposite end of the conductive sleeve indicates a break or other failure of the sleeve.

The electrical protection device 200 aims to test the mechanical/physical integrity of the electrical link 290 at the user apparatus 250 via a test of the electrical continuity of the conductive sleeve 280 over a defined test distance between the electronic devices 210, 245, 220 arranged in the secure housing 12 and the limiting electronic device 250a arranged in the secure housing 12a. The term ‘mechanical/physical integrity test’ is understood to mean the detection of a physical breakage of the electrical link 290 or a disconnection of the electrical link 290 from the secure housing 12a, in particular when the electrical link 290 is formed from a plurality of parts connected to one another via connectors (not shown), the detection of the opening of the electrical link 290 at a connector.

The secure housing 12a may be integrated into the user apparatus 250, thus making it possible to detect a disconnection of the electrical link 290 from the user apparatus 250.

The electronic devices 210, 220 and 245 arranged in the housing 12 (see FIG. 2) may comprise:

(i) a circuit breaker 210 connected to the electric power source 270 and, upon command, interrupts current from the electrical power source 270 to the user apparatus 250 via the electrical conductor 240. The circuit breaker 210 operates as a switch that, when commanded, opens and thus interrupts current through the electrical conductor 240;

(ii) a biasing module 245 for voltage-biasing the conductive sleeve 280; and

(iii) a detection module 220 for testing the mechanical integrity of the electrical link 290 via a test of the electrical continuity of the conductive sleeve 280.

With reference to FIG. 4, the biasing module 245 comprises a DC voltage source 245a supplying a voltage V_test_PSS to apply a voltage bias the conductive sleeve 280. The test voltage V_test_PSS delivered by the voltage source 245a is a relatively low voltage, such as less than 50 volts in terms of absolute value.

The biasing module 245 furthermore comprises a protective circuit 245b, such as for example a resistor in series or a current limiter (the limiter is shown in FIG. 4), that causes voltage fluctuations in the test voltage as it is applied to the conductive sleeve. The protective circuit 245b is in series between the DC voltage supply 245b and the conductive sleeve 280.

The test voltage may be applied to the conductive sleeve at a region of the sleeve nearest the end of the conductor connected to the high voltage DC power source 270. The voltage Vslev is the voltage on the conductive sleeve and is related to the test voltage applied to the conductive sleeve.

The voltage source 245a is connected in series between the current return line 260 and a first terminal of the protective circuit 245b. A second terminal of the protective circuit 245b is connected to the conductive sleeve 280.

The detection module 220 comprises a comparator 220a and a microcontroller 220b receiving as an input the output signal VComp of the comparator 220a. An output of the microcontroller 220b is applied to control the circuit breaker 210.

The microcontroller 220b receives an output signal VComp of the comparator 220a. The microcontroller 220b is configured to supply a command signal to the circuit breaker 210 to cause the circuit breaker to open and thereby interrupt current in the electrical link.

The conductive sleeve 280 is biased, such as continually, by the test voltage. The detection module 220 may continuously monitor the continuity of the conductive sleeve 280 and is ready to command the circuit breaker in the event of an anomaly in the conductivity of the conductive sleeve. The conductivity of the conductive sleeve is monitored based on the voltage Vslev on the conductive sleeve.

The comparator 220a is connected, at a first input, to the conductive sleeve 280, and, at a second input, to a DC voltage generator (not shown) supplying what is termed a reference voltage Vref.

The comparator 220a compares the voltage Vslev in the conductive sleeve 280 with the reference voltage Vref so as to test the mechanical/physical integrity of the electrical link 290. The output signal VComp of the comparator is in either: a first state (for example 0 in Boolean logic) indicative of an absence of a physical/mechanical integrity fault with the electrical link 290, or a second state (for example 1) indicative of a physical/mechanical integrity fault with the electrical link 290 (disconnection or breakage of the electrical link).

The reference voltage Vref is chosen depending on the value of the voltage Vlim of the limiting electronic device 250a, and depending on the value of the test voltage V_test_PSS. The negative input of the comparator 220a is linked to the DC voltage generator that supplies the reference voltage Vref. The reference voltage is lower than the voltage V_test_PSS.

The role of the limiting electronic device 250a arranged is to assist in detecting a break or failure of the conductive sleeve 280. The limiting electronic device 250a is at an end of the conductive sleeve opposite to the end connected to the biasing module 245 and the comparator 220. The limiting electronic device 250a limits the voltage on the conductive sleeve 280 to a level below the test voltage V_test_PSS provided by the DC voltage source 245b.

The limiting electronic device 250a may be a voltage-limiting diode, such as a Zener diode, with a limit voltage Vlim chosen such that the voltage limiter limits the voltage Vslev on the conductive sleeve to a level less than the test voltage V_test_PSS supplied by the voltage source 245d. Thus, Vlim is lower than the test voltage V_test_PSS. One terminal of the voltage-limiting diode 250a is connected to a first termination at an end of the conductive sleeve 280 at or near a user apparatus. The other terminal of the limiting electronic device 250a is connected to the current return line 260.

According to this example, the voltage Vref is equal to 40 volts for V_test_PSS at 45 volts and a limit voltage Vlim at 35 volts. The output signal VComp of the comparator 220a is in a first state (for example 0 in Boolean logic) as long as Vslev is lower than Vref (when there is no integrity fault with the sleeve 280), and changes to the second state (for example 1) when Vslev is greater than Vref (thereby indicating a breakage of the continuity of the conductive sleeve 280, and therefore potentially a disconnection of the electrical link 290).

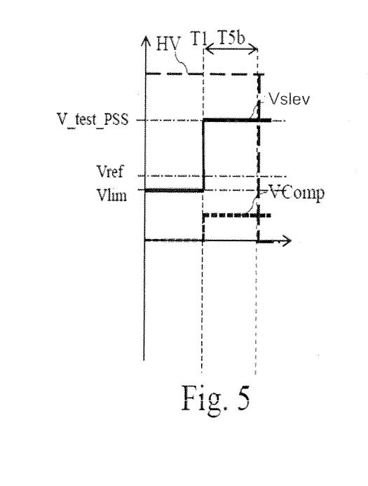

With reference to FIG. 5, what is shown is an example of the evolution of the signals Vref, Vslev, HV and VComp over time when, starting from a time T1, the electrical link 290 is disconnected from the user apparatus 250, the latter comprising the secure housing 12a.

In this example, the high-voltage power source 270 produces a positive voltage HV:

HV=540 volts,

Vref=40 volts,

V_test_PSS=45 volts,

Vlim=35 volts.

Before the time T1, there is no integrity fault with the conductive sleeve 280. Before the time T1, the signal Vslev on the conductive sleeve 280 is equal to Vlim. The output signal VComp of the comparator 220a is therefore in its first state, for example at 0 in Boolean logic.

Starting from the time T1, the continuity of the conductive sleeve 280 is broken. The break of the continuity of the conductive sleeve 280 interrupts current through the conductive sleeve. Thus, the limiting electronic device 250a at the far end of the conductive sleeve is no longer able to limit the voltage Vslev at the opposite end of the conductive sleeve near the electrical protection device. Because there is no limiting by the limiting electronic device 250a, the voltage on the conductive sleeve 280 is at the test voltage level V_test_PSS.

After T1, the voltage Vslev on the conductive sleeve 280 is equal to the test voltage V_test_PSS of 45 volts and is greater than the reference voltage Vref. Immediately after (or during a short period T5b such as a few milliseconds) the voltage Vslev becoming greater than the test voltage V_test_PSS, the comparator 220a issues an output signal VComp indicative of the second state of the comparator. Upon receiving the output signal VComp indicative of the second state, the microcontroller 220b immediately (or within a short period (T5b) commands the circuit breaker 210 to interrupt and thereby shut off current to the conductor 240 and to the user apparatus 250.

By virtue of the present invention, as soon as a breakage of the electrical continuity of the conductive sleeve 280 is detected, the circuit breaker is activated and current is interrupted in the electrical conductor 240. The response time between breakage of the electrical continuity and interruption of the circuit may be a brief reaction time (T5b) of the electronic circuits.

The voltage-biased conductive sleeve 280 thus forms a detector that is capable of detecting the disconnection or breakage of the conductive sleeve 280 which is indicative of a break in the electrical link 290. The fast cutting off (a few milliseconds) of the electric power secures possible interventions by maintenance staff by preventing the occurrence of electric arcing upon a disconnection of the electrical link from the user apparatus 250.

In the above description, current return line 260 is understood to mean either a return conductor or a current return network. If the current return line 266 is a conductor set to a voltage different from that of the conductive structure of the aircraft, then an electrical protection device such as described above will have to be associated with the current return line 260 in order to secure the current return.

The invention may be embodied to protect transmission of electric power via an electrical link of an electrical installation on an aircraft 10. The invention is applicable to any other type of vehicle, for example a boat or an automobile.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

The invention is:

1. An electrical link configured to link a DC high-voltage power source to an electrically powered user apparatus, wherein the electrical link comprises:
an electrical conductor within an insulating cover; and
an electrical protection device including:
a conductive sleeve covering the insulating cover;
a circuit breaker in series with the electrical conductor and configured to cut off a current transiting through the conductor;
a biasing module configured to voltage-bias the conductive sleeve with a DC test voltage;
a voltage limiting device configured to limit a voltage on the conductive sleeve to a limit voltage lower than the DC test voltage; and
a detection module connected to the conductive sleeve and configured to detect and respond to a voltage on the conductive sleeve higher than the limit voltage, wherein the response includes issuing a command to the circuit breaker to interrupt current to the conductor.

2. The electrical link according to claim 1, wherein the biasing module comprises a DC voltage source supplying the test voltage connected to the conductive sleeve.

3. The electrical link according to claim 1 wherein the detection module comprises:
a comparator including a first input is connected to the conductive sleeve and a second input receiving a reference voltage from a DC voltage generator; and
a microcontroller receiving an output of the comparator and configured to issue the command to the circuit breaker.

4. The electrical link according to claim 1, further comprising an insulating cover covering the conductive sleeve.

5. The electrical link according to claim 1 wherein the insulating cover has a first end region which is directly and conductively connected to the biasing module and to the detection module, and a second end region, opposite to the first end region, which is directly and conductively connected to the voltage limiting device.

6. The electrical link according to claim 5 wherein the voltage limiting device is in the electrically powered user apparatus connected to an electrically powered by the electrical conductor.

7. The electrical link according to claim 1 wherein the voltage limiting device includes a Zener diode in series between the conductive sleeve and a ground or return current path between the DC high voltage power source and the user apparatus.

8. An electrical link configured to supply electrical power to a user apparatus comprising:
an electrical conductor within an insulating sleeve connected to an electrical power source and connected to the user apparatus, wherein the conductor transmits electrical power from the electrical power source to the user apparatus;
a circuit breaker in series between the electrical conductor and the electrical power source;
a conductive sleeve covering the insulating sleeve covering the electrical conductor, wherein the conductive sleeve includes a first sleeve end region and a second sleeve end region, wherein the conductive sleeve extends laterally and continuously over the electrical conductor from the first sleeve end region to the second sleeve end region;
a biasing module including a DC power source supplying a DC test voltage, a physical connection to the first sleeve end region and an electrical path from the DC power source to the physical connection through which the DC test voltage is applied to the conductive sleeve;
a voltage limiting device connected to the second sleeve end region and configured to limit a voltage on the conductive sleeve to a limit voltage lower than the DC test voltage; and
a detection module electrically connected to the first sleeve end region, and configured to detect and respond to a voltage on the conductive sleeve higher than the limit voltage, wherein the response includes issuing a command to the circuit breaker to interrupt current to the electrical conductor.

9. The electrical link according to claim 8 wherein the detection module comprises:
a comparator including a first input electrically connected to the first sleeve end region and a second input receiving a reference voltage from a DC voltage generator; and
a controller receiving an output of the comparator and configured to issue the command to the circuit breaker.

10. The electrical link according to claim 8, further comprising an insulating cover covering the conductive sleeve.

11. The electrical link according to claim 8, wherein the voltage limiting device is in the electrically powered user apparatus.

12. The electrical link according to claim 8, wherein the voltage limiting device includes a Zener diode in series between the conductive sleeve and a ground or return current path between the DC high voltage power source and the user apparatus.

13. The electrical link according to claim 8 wherein the electrical power source supplied direct current (DC).

14. The electrical link according to claim 8 wherein the electrical conductor, the electrical power source and the user apparatus are in an aircraft.

15. The electrical link according to claim 8 wherein the first sleeve end region is aligned with a first end region of the electrical conductor connected to the electrical power source, and the second sleeve end region is aligned with a second end region of the electrical conductor connected to the user apparatus.

16. A method to interrupt current in an electrical link comprising:
supplying electrical power from an electrical power source in a vehicle, through a conductor with an insulating sleeve to a user apparatus in the vehicle;
applying a DC test voltage to a conductive sleeve on the insulating sleeve on the conductor through a first direct connection at a first end region of the conductive sleeve conductively connected to a source of the DC test voltage;
limiting voltage on the conductive sleeve to a voltage limit level below the DC test voltage by a second direct connection at a second end region of the conductive sleeve, wherein the second direct connection is conductively connected to a voltage limiting device;
at least periodically, comparing the voltage on the conductive sleeve at the first end region to a reference voltage which is greater than the voltage limit level and lower than the DC test voltage; and
if the comparison determines the voltage on the conductive sleeve is greater than the reference voltage, causing a circuit breaker to interrupt the electrical power flowing from the electrical power source to the conductor.

17. The method of claim 16 wherein the step of causing the circuit breaker to interrupt the electrical power is performed within ten milliseconds of the comparison determining the voltage on the conductive sleeve is greater than the reference voltage.

18. The method of claim 16 wherein the comparison is performed by a comparator receiving as inputs the voltage on the conductive sleeve and the DC test voltage, and the determination is automatically performed by a controller receiving an output signal from the comparator.
